(19) United States
(12) Patent Application Publication
(10) Pub. No.: US 2024/0309512 A1
(43) Pub. Date: Sep. 19, 2024

(54) METHOD OF MANUFACTURING LIQUID METAL FILM USING IMBIBITION PHENOMENA

(71) Applicant: Foundation for Research and Business, Seoul National University of Science and Technology, Seoul (KR)

(72) Inventors: Hyung Jun KOO, Seoul (KR); Ji Hye KIM, Seoul (KR)

(73) Assignee: Foundation for Research and Business, Seoul National University of Science and Technology, Seoul (KR)

(21) Appl. No.: 18/406,305

(22) Filed: Jan. 8, 2024

(30) Foreign Application Priority Data
Mar. 15, 2023 (KR) 10-2023-0034067
Apr. 11, 2023 (KR) 10-2023-0047330

(51) Int. Cl. C23C 28/02; C23C 14/20; C23C 14/24; C23C 14/58; C23C 24/04

(52) U.S. Cl. CPC C23C 28/021; C23C 14/20; C23C 14/24; C23C 14/58; C23C 24/04

(57) ABSTRACT

A method of manufacturing a liquid metal film using an imbibition phenomenon is provided. The method includes forming a microstructure on a polymer substrate, preparing a microstructured metal substrate by depositing a metal on the polymer substrate on which the microstructure is formed, and coating the microstructured metal substrate with a liquid metal.

### CROSS-REFERENCES TO RELATED APPLICATION

This application claims the benefit of priority of Korean Patent Application No. 10-2023-0034067 filed on Mar. 15, 2023, and Korean Patent Application No. 10-2023-0047330 filed on Apr. 11, 2023, the contents of which are incorporated by reference as if fully set forth herein in their entirety.

### FIELD AND BACKGROUND OF THE INVENTION

### 1. Field of the Invention

One or more embodiments relate to a method of manufacturing a liquid metal film using an imbibition phenomenon.

### 2. Description of the Related Art

Recently, as an interest in wearable devices increases, research is being actively conducted on stretchable electrodes to apply stretchable electrodes to wearable devices. Since existing metal electrodes are easily damaged even at low tensile force when applied to flexible and stretchable devices, research is being actively conducted to utilize liquid metals with high conductance and resistance to strain as electrodes as one of developments of flexible and stretchable electrodes.

To use liquid metals as electrodes, modification and coating technologies associated with liquid metals are essential. Existing liquid metal coating methods include a deposition process, a stencil process, and a blade process. Although such methods are simple, it is difficult to control the thickness of a film due to a high surface tension of the liquid metal and the uniformity of the film decreases. In addition, methods using a thermal evaporator, an electron beam evaporator, and sputtering may be used to obtain a uniform film but require expensive equipment and a complicated process.

Accordingly, a method of forming a liquid metal film and a pattern using properties of forming alloys of liquid metals is being studied. However, when a liquid metal and a metal substrate meet directly to form an alloy, an incomplete wetting phenomenon appears while maintaining a finite contact angle on a flat metal substrate, although a wetting phenomenon of the liquid metal occurs. In addition, since an additional external force such as a physical force or electrical force is required to induce a formation of an alloy between the liquid metal and other metals, the complexity of the process increases.

The above description has been possessed or acquired by the inventor(s) in the course of conceiving the present disclosure and is not necessarily an art publicly known before the present application is filed.

### SUMMARY OF THE INVENTION

Embodiments provide a method of manufacturing a liquid metal film using an imbibition phenomenon of a liquid metal on a surface of a metal substrate on which a microstructure is formed, and a method of manufacturing a liquid metal film using an imbibition phenomenon of a liquid metal on a surface of a metal nanoparticle-coated substrate, on which a nano-microstructure is formed, using spray coating.

Specifically, since a method of manufacturing a liquid metal film using a microstructured metal substrate according to an embodiment does not require expensive equipment and external force, embodiments provide a method that may enable coating within a relatively short time.

Specifically, a method of manufacturing a liquid metal film using spray coating according to an embodiment provides a simple manufacturing method that does not require an additional process for forming a nano-microstructure.

However, goals obtainable from the present disclosure are not limited to the above-mentioned goal, and other unmentioned goals can be clearly understood from the following description by one of ordinary skill in the art to which the present disclosure pertains.

According to an aspect, a method of manufacturing a liquid metal film includes forming a microstructure on a polymer substrate, preparing a microstructured metal substrate by depositing a metal on the polymer substrate on which the microstructure is formed, and coating the microstructured metal substrate with a liquid metal.

According to an embodiment, the polymer substrate may include at least one of polydimethylsiloxane (PDMS), polyurethane acrylate (PUA), poly(vinyl alcohol) (PVA), polyvinyl chloride (PVC), polytetrafluoroethylene (PTFE), styrene ethylene butylene styrene (SEBS), polyolefin, polystyrene, polyester, polyacrylate, polyimide, and Ecoflex. The metal may include at least one of copper, gold, chromium, silver, platinum, zinc, nickel, tin, and iron. The liquid metal may include gallium, or a gallium-based alloy including gallium and at least one metal among indium, tin, and zinc.

According to an embodiment, the forming of the microstructure may be performed by a photolithography process, a soft lithography process, a nanoimprinting process, a three-dimensional (3D) printer process, a particle coating method, or a surface grinding method.

The microstructure may include at least one structure among a cylinder, a pyramid, a hemisphere, and a polygonal pillar. The microstructure may have a height of about 1 micrometer (μm) to about 200 μm, a width of about 1 μm to about 200 μm, and a pitch of about 1 μm to about 100 μm.

According to an embodiment, the preparing of the microstructured metal substrate by depositing the metal may be performed by a vacuum deposition process. The coating of the microstructured metal substrate with the liquid metal may be performed by an acid vapor treatment of the liquid metal on the microstructured metal substrate. The acid vapor treatment may be a treatment of vapor of at least one acid solution among a hydrochloric acid, a nitric acid, a sulfuric acid, a bromic acid, and a perchloric acid.

According to an embodiment, the coating of the microstructured metal substrate with the liquid metal may include coating the microstructured metal substrate with the liquid metal while the liquid metal spontaneously and selectively flows along the microstructure. The liquid metal applied onto the microstructured metal substrate may have a thickness of about 1 μm to about 200 μm.

According to another aspect, a method of manufacturing a liquid metal film includes preparing a metal nanoparticle-coated substrate by spray coating a polymer or silicon substrate with metal nanoparticles, and coating the metal nanoparticle-coated substrate with a liquid metal.

According to an embodiment, the method may further include, prior to the preparing of the metal nanoparticle-coated substrate, forming a metal layer by depositing a metal on the polymer or silicon substrate.

According to an embodiment, the polymer substrate may include at least one of polydimethylsiloxane (PDMS), polymethyl methacrylate (PMMA), polyurethane acrylate (PUA), polytetrafluoroethylene (PTFE), styrene ethylene butylene styrene (SEBS), polypropylene, polystyrene, polyester, polyimide, and Ecoflex. The metal may include at least one of copper, gold, silver, platinum, zinc, nickel, tin, and iron. The metal nanoparticles may include at least one of copper, gold, silver, platinum, zinc, nickel, tin, and iron. The liquid metal may include gallium, or a gallium-based alloy including gallium and at least one metal among indium, tin, and zinc.

According to an embodiment, a solution used for the spray coating may include at least one solvent among dichloromethane, acetone, methyl alcohol, ethyl alcohol, isopropyl alcohol, tetrahydrofuran, dimethylformamide, hexane, cyclohexanone, toluene, chloroform, dichlorobenzene, acrylonitrile, and dimethyl sulfoxide. The metal nanoparticles may be in an amount of about 0.1% by weight (wt %) to about 80 wt % in the solution. The metal nanoparticles may have a size of about 100 nanometers (nm) to about 500 μm. The spray coating may be performed at a distance of about 5 centimeters (cm) to about 50 cm and a velocity of about 1 microliter per second (μL/s) to about 10 milliliters per second (mL/s) for a period of about 1 second to about 20 minutes.

According to an embodiment, the metal nanoparticle-coated substrate may form a metal surface with a nano-microstructure. The nano-microstructure may have a size of about 500 nm to about 500 μm. The coating of the metal nanoparticle-coated substrate with the liquid metal may include coating the metal nanoparticle-coated substrate with the liquid metal while the liquid metal spontaneously and selectively flows along the nano-microstructure. The liquid metal applied onto the metal nanoparticle-coated substrate may have a thickness of about 500 nm to about 500 μm.

Additional aspects of embodiments will be set forth in part in the description which follows and, in part, will be apparent from the description, or may be learned by practice of the disclosure.

Embodiments may provide a method of manufacturing a liquid metal film using an imbibition phenomenon of a liquid metal on a surface of a metal substrate on which a microstructure is formed and manufacturing a liquid metal film using an imbibition phenomenon of a liquid metal on a surface of a metal nanoparticle-coated substrate, on which a nano-microstructure is formed, using spray coating.

Specifically, the method of manufacturing the liquid metal film may provide a spontaneous and uniform coating technology of a liquid metal, which is uncontrollable due to its high surface tension, using an imbibition phenomenon of the liquid metal on a surface of the microstructure. In addition, expensive equipment may not be necessary, rapid coating may be possible, and selective patterning of a liquid metal may be possible by controlling a microstructured region.

Specifically, the method of manufacturing the liquid metal film using the spray coating may provide a simple manufacturing method that does not require an additional process for forming a nano-microstructure. A spontaneous and easy method of manufacturing a liquid metal film without a need for expensive equipment and a complicated process may be provided, and thus, a simplification of a manufacturing process and shortening of a process time may be expected.

### BRIEF DESCRIPTION OF THE SEVERAL VIEWS OF THE DRAWINGS

These and/or other aspects, features, and advantages of the invention will become apparent and more readily appreciated from the following description of embodiments, taken in conjunction with the accompanying drawings of which:

FIG. 1 illustrates a method of manufacturing a liquid metal film according to an embodiment;

FIG. 2 illustrates a liquid metal selectively applied onto a microstructured metal substrate according to an embodiment;

FIG. 3 illustrates a contact angle of a liquid metal according to examples and comparative examples of the present disclosure;

FIG. 4 illustrates a contact angle of a liquid metal according to examples and comparative examples of the present disclosure;

FIG. 5 is a diagram schematically illustrating an example of a method of manufacturing a liquid metal film according to an embodiment;

FIG. 6 is a diagram schematically illustrating another example of a method of manufacturing a liquid metal film according to an embodiment;

FIG. 7 illustrates an example of a liquid metal applied according to an embodiment; and

FIG. 8 illustrates another example of a liquid metal applied according to an embodiment.

### DESCRIPTION OF SPECIFIC EMBODIMENTS OF THE INVENTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure. In addition, terms such as first, second, A, B, (a), (b), and the like may be used to describe components of the embodiments. These terms are used only for the purpose of discriminating one component from another component, and the nature, the sequences, or the orders of the components are not limited by the terms. It should be noted that if one component is described as being “connected”, “coupled” or “joined” to another component, the former may be directly “connected”, “coupled”, and “joined” to the latter or “connected”, “coupled”, and “joined” to the latter via another component.

A component, which has the same common function as a component included in any one embodiment, will be described by using the same name in other embodiments. Unless otherwise described, the description on one embodiment may be applicable to another embodiment and thus, redundant description will be omitted for conciseness.

According to an embodiment, a method of manufacturing a liquid metal film may include forming a microstructure on a polymer substrate, preparing a microstructured metal substrate by depositing a metal on the polymer substrate on which the microstructure is formed, and coating the microstructured metal substrate with a liquid metal.

The liquid metal may refer to a liquid derived from free electrons and metal ions such as mercury or molten metal and may have a property of easily conducting electricity due to activities of free electrons. In addition, it is known that a wetting phenomenon of the liquid metal is induced on a solid metal due to properties of forming alloys with other metals. However, a wetting phenomenon that occurs on a flat metal substrate may show an incomplete wetting phenomenon while maintaining a finite contact angle (about 25°). In the method of manufacturing the liquid metal film, an imbibition phenomenon of the liquid metal may be used. The imbibition phenomenon may indicate that the liquid metal shows a behavior as if the liquid metal is absorbed along a microstructure while forming an alloy with a metal layer. A spontaneous spreading of the liquid metal caused by the imbibition phenomenon may remarkably appear along the microstructure. Therefore, in the present disclosure, a microstructure may be formed on a polymer substrate, a metal may be deposited, and the liquid metal may form an alloy with the metal on which the microstructure is formed, so that an excellent imbibition phenomenon and complete wetting phenomenon may occur. By patterning a microstructured region based on the excellent imbibition and complete wetting phenomena, selective coating and patterning of the liquid metal may also be possible. In addition, a fast and reproducible new liquid metal coating and pattern formation technology that may induce complete wetting in which a contact angle of a liquid metal converges to 0° may be provided.

According to an embodiment, the polymer substrate may include at least one of polydimethylsiloxane (PDMS), polyurethane acrylate (PUA), poly(vinyl alcohol) (PVA), polyvinyl chloride (PVC), polytetrafluoroethylene (PTFE), styrene ethylene butylene styrene (SEBS), polyolefin, polystyrene, polyester, polyacrylate, polyimide, and Ecoflex. The metal may include at least one of copper, gold, chromium, silver, platinum, zinc, nickel, tin, and iron. The liquid metal may include gallium, or a gallium-based alloy including gallium and at least one metal among indium, tin, and zinc.

The polymer substrate may be a flexible material that may be used in a wearable device and may function as a substrate on which a microstructure is easily formed and that may maintain the microstructure.

A metal may induce a wetting phenomenon of a liquid metal by forming an alloy with the liquid metal, and the liquid metal may have poor affinity with the polymer substrate, and thus, the metal may function as an intermediate layer connecting the polymer substrate and the liquid metal. As the metal, a metal that is less damaged by an acid vapor treatment during coating with the liquid metal may desirably be used.

The liquid metal may refer to a metal in a liquid state and have electrical conductivity. In particular, since a gallium-based liquid metal has properties of easily forming an alloy with other metals, the liquid metal and a metal substrate may meet to form an alloy so that a wetting phenomenon of the liquid metal may occur. The liquid metal may desirably be a eutectic gallium (Ga)-indium (In) alloy (EGaIn) or a gallium-indium-tin alloy (Galinstan). The EGaIn may be formed of gallium and indium in a weight ratio of 3:1 and may have a melting point of about 15.5° C. and physical properties of a liquid at room temperature. In addition, since the shape of the EGaIn may be easily deformed and restored by an external physical force, the EGaIn may be used in a flexible electronic device, and the like.

According to an embodiment, the forming of the microstructure may be performed by a photolithography process, a soft lithography process, a nanoimprinting process, a three-dimensional (3D) printer process, a particle coating method, or a surface grinding method.

The surface grinding method may refer to a method of grinding a surface such as sand papering. To form a microstructure on the polymer substrate, the soft lithography process may desirably be performed. The soft lithography process may be used to transfer a pattern of microstructures formed on a silicon wafer to a polymer substrate. A pattern of microstructures may be formed through the photolithography process.

The microstructure may include at least one structure among a cylinder, a pyramid, a hemisphere, and a polygonal pillar. The microstructure may have a height of 1 micrometer (μm) to about 200 μm, a width of about 1 μm to about 200 μm, and a pitch of about 1 μm to about 100 μm.

The microstructure may be formed by repeating one structure at regular intervals and may desirably be a cylindrical structure. When a microstructure is formed with a cylindrical structure, it may be easy to transfer a pattern to a polymer substrate and isotropic coating may be possible.

The size of the microstructure may be expressed as a height and a width. Here, the width may refer to a diameter in the case of a cylindrical structure, and may refer to a length of a base of a pyramid in the case of a pyramid structure. The pitch, which is a center-to-center distance, may refer to a gap between a center of an object or a specific portion (e.g., a tip, a point, etc.). In the case of the cylindrical structure, the pitch may refer to a distance between centers of circles, and in the case of the pyramid structure, the pitch may refer to a distance between vertices of a pyramid.

When the height, the width, and the pitch of the microstructure are out of the above ranges, an imbibition phenomenon of a liquid metal may not occur so that a complete wetting phenomenon may fail to occur, and accordingly, it may be impossible to form a liquid metal film. In particular, as the width and the pitch increase, the imbibition phenomenon may be weakened.

The microstructure may desirably have a height of 1 μm to 150 μm, 5 μm to 150 μm, 5 μm to 100 μm, 10 μm to 100 μm, or 10 μm to 40 μm, and more desirably have a height of 10 μm to 30 μm. The microstructure may desirably have a width of 1 μm to 100 μm, 10 μm to 100 μm, or 10 μm to 50 μm, and more desirably have a width of 10 μm to 30 μm. The microstructure may desirably have a pitch of 10 μm to 100 μm. A ratio of the height:the width:the pitch of the microstructure may desirably be in a range of 1:1:1 to 1:2:4. When the ratio is out of the range, the imbibition phenomenon may not occur due to an increase in a gap between microstructures in comparison to the size of the microstructure.

According to an embodiment, the preparing of the microstructured metal substrate by depositing the metal may be performed by a vacuum deposition process.

The metal deposited by vacuum deposition may form a metal layer. The metal layer may have a thickness of 50 nm to 500 nm. The deposited metal may be deposited while maintaining a microstructure on a substrate and may stably induce the imbibition phenomenon of the liquid metal. A microstructure may be formed on a polymer substrate and a metal thin film may be deposited, and accordingly, use of a metal in preparing a metallic surface having a microstructure may be minimized, thereby reducing processing costs.

The coating of the microstructured metal substrate with the liquid metal may be performed through an acid vapor treatment of the liquid metal on the microstructured metal substrate. The acid vapor treatment may be a treatment of vapor of at least one acid solution among a hydrochloric acid, a nitric acid, a sulfuric acid, a bromic acid, and a perchloric acid.

Since an oxide film in the form of a viscous gel is formed on a surface of a liquid metal droplet on a metal substrate, the liquid metal droplet may not form an alloy with the metal substrate. Accordingly, the acid vapor treatment may be performed to remove the oxide film. When the acid vapor treatment is performed, the oxide film may be removed from the surface of the liquid metal, so that a surface formed of a metal material may exhibit a high wettability, and the wetting phenomenon of the liquid metal may occur while the liquid metal and the metal substrate directly meet to form an alloy.

In the acid vapor treatment to remove the oxide film from the surface of the liquid metal, a concentration of the acid solution may be important. When the concentration of the acid solution is low, the oxide film formed on the surface of the liquid metal may not be completely removed, and accordingly, an alloy with a metal may fail to be formed, so that a wetting phenomenon may not be induced. When the concentration of the acid solution is high, a deposited metal layer may be etched, and accordingly, it may be difficult to form a uniform liquid metal film. The concentration of the acid solution in the acid vapor treatment may be desirably in a range of 30% by weight (wt %) to 38 wt %.

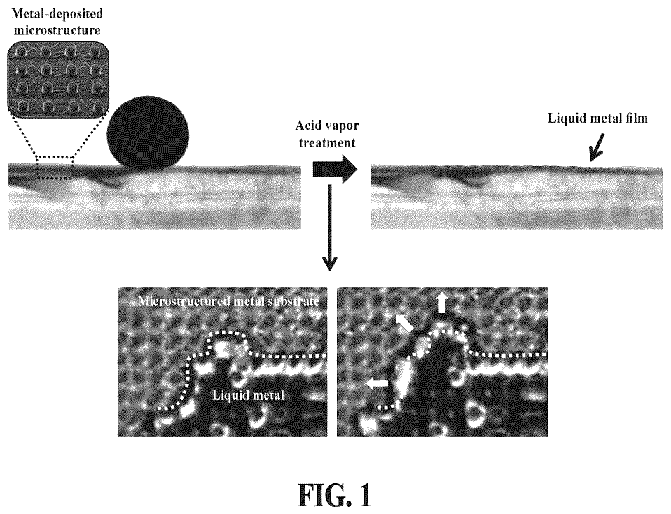

FIG. 1 illustrates a method of manufacturing a liquid metal film according to an embodiment. Referring to FIG. 1, a microstructured metal substrate prepared by depositing a metal on a polymer substrate on which a cylindrical microstructure is formed may be coated with a liquid metal. When an acid vapor treatment is performed on the liquid metal present as liquid droplets by an oxide film, a contact angle may decrease as the oxide film is removed, imbibition may start from an edge of a droplet, and a wetting phenomenon may occur. Accordingly, it can be confirmed that as the imbibition phenomenon appears along a microstructure of the microstructured metal substrate, complete wetting of the liquid metal is realized to form a liquid metal film.

According to an embodiment, in the coating of the microstructured metal substrate with the liquid metal, the liquid metal may be spontaneously and selectively applied to the microstructured metal substrate along the microstructure.

In general, coating to form a liquid metal film includes a stencil process, a blade process, a spray process, and the like, and requires an additional external force for coating, however, in the coating of the microstructured metal substrate with the liquid metal, the liquid metal may be spontaneously and thinly applied onto the microstructured metal substrate while flowing along a microstructure pattern.

When a liquid metal droplet is dropped and treated with acid vapor, a uniform liquid metal film may be formed through a complete wetting phenomenon as the liquid metal spontaneously spreads along a microstructured region due to the imbibition phenomenon. The complete wetting phenomenon may appear within one minute after the acid vapor treatment, and coating may be completed quickly and uniformly without an additional external force. This is a new spontaneous coating method, which is different from general coating by an external force such as pressure or rolling, and selective coating of the liquid metal may be performed by patterning the microstructure region into a desired shape without an additional process.

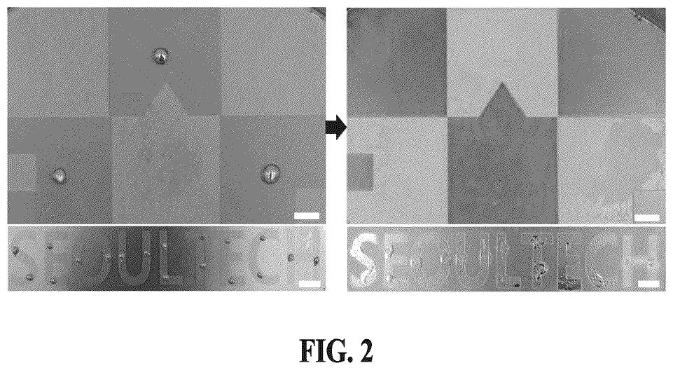

FIG. 2 illustrates a liquid metal selectively applied onto a microstructured metal substrate according to an embodiment. Referring to FIG. 2, it can be confirmed that since a spontaneous spreading phenomenon due to an imbibition phenomenon of the liquid metal remarkably appears along a microstructure, selective coating and patterning of the liquid metal is possible by patterning a microstructured region. An imbibition of the liquid metal may occur on only a surface on which the microstructure is formed, and when the liquid metal contacts a flat surface on which a microstructure is not formed, the imbibition phenomenon may stop. As a result, it can be confirmed that the liquid metal may be precisely, spontaneously, and selectively applied even at a boundary through a sharp boundary line. In the case of letters used in FIG. 2, it can be observed that the liquid metal invades a non-patterned region around positions in which liquid metal droplets are initially placed. However, the above invasion occurs due to a minimum diameter of the liquid metal droplets and may be solved by adjusting the size of the liquid metal droplets. Since a scale bar in FIG. 2 is 5 mm, it can be confirmed that the liquid metal may be applied even in a wide range of a centimeter (cm) scale.

The liquid metal applied onto the microstructured metal substrate may have a thickness of about 1 μm to about 200 μm.

The thickness of the applied liquid metal may be a thickness of a liquid metal film. Since the thickness of the applied liquid metal is almost identical to a height of the microstructure, the thickness of the liquid metal film may be adjusted by adjusting the size of the microstructure, a uniform liquid metal film may be provided, and the liquid metal may be spontaneously and thinly applied over a large area without a complicated process.

In the present disclosure, a new coating and pattern formation technology using an imbibition phenomenon of a liquid metal on a surface of a metal substrate on which a microstructure is formed may be provided. The above method of manufacturing the liquid metal film may provide a stable, spontaneous and rapid coating technology using a liquid metal, which is uncontrollable due to its high surface tension, and may enable coating to be performed over a wide range within a relatively short time because there is no need for expensive equipment or external force. In addition, by controlling the microstructured region, selectively patterning of the liquid metal may be possible. The above spontaneous and easy method of manufacturing the liquid metal film may be a core technology to allow a liquid metal to be more actively used as an electrode material of a portable wearable device. Based on the above technology, the development of electrode materials using liquid metals is expected to accelerate the development of ultra-flexible/ultra-stretchable electrodes that exceed existing performance.

According to an embodiment, a method of manufacturing a liquid metal film may include preparing a metal nanoparticle-coated substrate by spray coating a polymer or silicon substrate with metal nanoparticles, and coating the metal nanoparticle-coated substrate with a liquid metal.

It is known that a wetting phenomenon of the liquid metal is induced on a metal due to properties of forming alloys with other metals. However, a wetting phenomenon that occurs on a flat metal substrate may show an incomplete wetting phenomenon while maintaining a finite contact angle (about 25°). In the method of manufacturing the liquid metal film, an imbibition phenomenon of the liquid metal may be used. The imbibition phenomenon may indicate that the liquid metal shows a behavior as if the liquid metal is absorbed along a nano-microstructure while forming an alloy with a metal. A spontaneous spreading of the liquid metal caused by the imbibition phenomenon may remarkably appear along the nano-microstructure and may be selective.

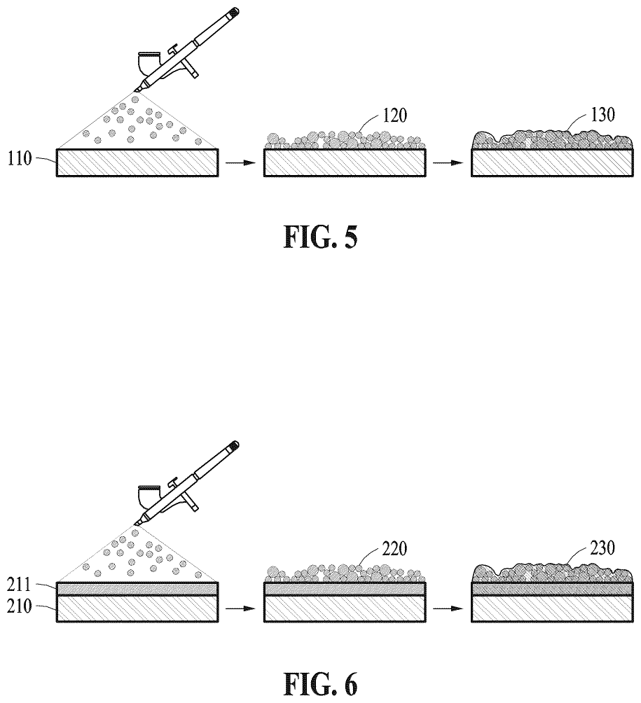

FIG. 5 is a diagram schematically illustrating an example of a method of manufacturing a liquid metal film according to an embodiment. Referring to FIG. 5, when spray coating with a solution containing metal nanoparticles is performed, a polymer substrate 110 may be coated with metal nanoparticles 120 to prepare a metal nanoparticle-coated substrate on which a nano-microstructure is formed. To form a nano-microstructure, a complicated process such as a photolithography process is generally required. However, in the present disclosure, the nano-microstructure may be easily formed through only a spray process while applying the metal nanoparticles 120. A liquid metal 130 may exhibit an excellent imbibition phenomenon along the nano-microstructure while forming an alloy with the metal nanoparticles 120 and may be spontaneously applied onto the metal nanoparticle-coated substrate through complete wetting. By patterning a nano-microstructure region based on the excellent imbibition phenomenon and complete wetting, selective coating and patterning of a liquid metal may also be possible. In addition, a fast and reproducible new liquid metal coating and pattern formation technology that may induce complete wetting in which a contact angle of a liquid metal converges to 0° may be provided.

According to an embodiment, the method may further include, prior to the preparing of the metal nanoparticle-coated substrate, forming a metal layer by depositing a metal on the polymer or silicon substrate.

The forming of the metal layer by depositing the metal may be performed by a vacuum deposition process. Since metal nanoparticles fail to be bonded onto the polymer or silicon substrate, an alloy with the liquid metal may not be smoothly formed. Accordingly, by depositing the metal, a bonding strength between the polymer or silicon substrate and the metal nanoparticles may be increased. The metal layer may have a thickness of about 50 nm to about 200 nm. When the thickness of the metal layer is within the above range, a formation of an alloy with a liquid metal may be induced and a consumption of the metal may be minimized.

FIG. 6 is a diagram schematically illustrating another example of a method of manufacturing a liquid metal film according to an embodiment. Referring to FIG. 6, a metal layer 211 may be formed by depositing a metal on a polymer substrate 210. When spray coating is performed on the polymer substrate 210, on which the metal layer 211 is formed, using a solution containing metal nanoparticles, the polymer substrate 210 may be coated with metal nanoparticles 220 to prepare a metal nanoparticle-coated substrate on which a nano-microstructure is formed. A liquid metal 230 may exhibit an excellent imbibition phenomenon along the nano-microstructure while forming an alloy with the metal nanoparticles 220 and may be spontaneously applied onto the metal nanoparticle-coated substrate through complete wetting.

According to an embodiment, the polymer substrate may include at least one of polydimethylsiloxane (PDMS), polymethyl methacrylate (PMMA), polyurethane acrylate (PUA), polytetrafluoroethylene (PTFE), styrene ethylene butylene styrene (SEBS), polypropylene, polystyrene, polyester, polyimide, and Ecoflex. The metal may include at least one of copper, gold, silver, platinum, zinc, nickel, tin, and iron. The metal nanoparticles may include at least one of copper, gold, silver, platinum, zinc, nickel, tin, and iron. The liquid metal may include gallium, or a gallium-based alloy including gallium and at least one metal among indium, tin, and zinc.

The polymer substrate may be a flexible material that may be used for a wearable device, and a polymer layer melted due to use of an appropriate solvent may function to fix metal particles.

The metal may be deposited on a polymer or silicon substrate and may function as an intermediate layer to enhance a bonding strength between the polymer or silicon substrate and metal nanoparticles.

The metal nanoparticles may form an alloy with the liquid metal to induce a wetting phenomenon of the liquid metal. Since the liquid metal and the polymer or silicon substrate are not bonded, the metal nanoparticles may function to connect the liquid metal and the polymer or silicon substrate.

The liquid metal may refer to a metal that is in a liquid state at room temperature and may have electrical conductivity. In particular, since a gallium-based liquid metal has properties of easily forming an alloy with other metals, the liquid metal and a metal substrate may meet to form an alloy so that a wetting phenomenon of the liquid metal may occur. The liquid metal may desirably be a eutectic gallium (Ga)-indium (In) alloy (EGaIn) or a gallium-indium-tin alloy (Galinstan). The EGaIn may be formed of gallium and indium in a weight ratio of 3:1 and may have a melting point of about 15.5° C. and physical properties of a liquid at room temperature.

According to an embodiment, a solution used for the spray coating may include at least one solvent among dichloromethane, acetone, methyl alcohol, ethyl alcohol, isopropyl alcohol, tetrahydrofuran, dimethylformamide, hexane, cyclohexanone, toluene, chloroform, dichlorobenzene, acrylonitrile, and dimethyl sulfoxide.

For example, when the metal nanoparticles are sprayed directly onto the polymer or silicon substrate, the metal nanoparticles may not properly be attached to the polymer or silicon substrate. In this example, a phenomenon in which metal nanoparticles peel off as the liquid metal absorbs the metal nanoparticles may occur in a process of coating with the liquid metal, and accordingly, the metal nanoparticles may need to be stably fixed to a substrate. To this end, using of a liquid capable of partially melting or swelling a substrate as a solvent of a spray solution may be advantageous to increase the bonding strength between the polymer or silicon substrate and metal nanoparticles. A surface of a substrate melted by an appropriate solvent may function as an adhesive, and accordingly, metal nanoparticles may be stably fixed to the substrate. On the substrate stably coated with metal particles, a spontaneous wetting phenomenon of the liquid metal along the nano-microstructure by the metal nanoparticles may occur.

Desirably, the solvent may be adjusted according to the type of polymer substrates. Desirably, PMMA and dichloromethane may be used as a substrate and a solvent, respectively, PDMS or SEBS and toluene may be used as a substrate and a solvent, respectively, or polypropylene and acetone may be used as a substrate and a solvent, respectively. When a polymer substrate and a spray solvent are used based on the above combinations, a bonding stability between the metal nanoparticles and the substrate may be greatly enhanced while minimizing damage to the polymer substrate after spray coating.

The metal nanoparticles may be in an amount of about 0.1 wt % to about 80 wt % in the solution, and may have a size of about 100 nm to about 500 μm. The spray coating may be performed at a distance of about 5 cm to about 50 cm and a velocity of about 1 microliter per second (μL/s) to about 10 milliliters per second (mL/s) for a period of about 1 second to about 20 minutes.

Desirably, the metal nanoparticles may be in an amount of about 0.1 wt % to about 50 wt %, about 0.5 wt % to about 50 wt %, about 0.5 wt % to about 25 wt %, about 1 wt % to about 25 wt %, or about 1 wt % to about 10 wt % in the solution. If the amount of the metal nanoparticles in the solution is less than 0.1 wt %, a large amount of time may be required to form nano-micro roughness. If the amount of the metal nanoparticles exceeds 80 wt %, the metal nanoparticles may be less dispersed in the solvent or a spray nozzle may be clogged.

If the size of the metal nanoparticles is less than 100 nm, nano-microroughness may not be sufficiently formed. If the size of the metal nanoparticles exceeds 500 μm, a dispersion stability may decrease or it may be difficult to perform coating with the liquid metal because the imbibition phenomenon does not occur due to the size of the metal nanoparticles.

The spray coating may be performed under conditions of room temperature and pressure and may have an influence on a formation of a nano-microstructure depending on specific conditions.

If the distance of the spray coating is less than 5 cm, the solvent and metal particles may fail to be stably attached to the substrate due to a spray pressure, which may result in uneven coating. If the distance exceeds 50 cm, the solvent may evaporate in the air, thereby failing to melt the polymer substrate when the solvent meets the polymer substrate.

Desirably, the spray time may be a period of about 1 second to about 15 minutes, about 10 seconds to about 15 minutes, about 10 seconds to about 10 minutes, about 30 seconds to about 10 minutes, about 30 seconds to about 5 minutes, or about 1 minute to about 5 minutes. If the spray time is less than 1 second, the imbibition phenomenon of the liquid metal may not occur due to an insufficient metal particle coating layer. If the spray time exceeds 20 minutes, metal particles may be wasted after a subsequent time because the metal particles are sufficiently applied.

If the spray velocity is less than 1 μL/s, a nozzle may be clogged with metal particles or coating with particles may be performed at an extremely low velocity. If the spray velocity exceeds 10 mL/s, the solvent may not smoothly evaporate, which may cause metal particles to fail to be stably accumulated on the surface, or the solvent and the metal particles may not be uniformly applied to the substrate due to a high spray pressure.

The coating of the metal nanoparticle-coated substrate with the liquid metal may be performed through an acid vapor treatment of the liquid metal on the metal nanoparticle-coated substrate. The acid vapor treatment may be a treatment of vapor of at least one acid solution among a hydrochloric acid, a nitric acid, a sulfuric acid, a bromic acid, and a perchloric acid. Acid vapor may remove an oxide film from a surface of the liquid metal so that the liquid metal may directly contact the metal nanoparticles.

Since an oxide film in the form of a viscous gel is formed on a surface of a liquid metal droplet on the metal nanoparticle-coated substrate, the liquid metal droplet may not form an alloy with the metal substrate. Accordingly, the acid vapor treatment may be performed to remove the oxide film. When an acid vapor treatment is performed on the liquid metal present as liquid droplets due to the oxide film, the contact angle may decrease as the oxide film of the liquid metal is removed, and imbibition may start from an edge of the liquid droplets, which may cause a wetting phenomenon. Accordingly, the complete wetting of the liquid metal may occur as the imbibition phenomenon appears along the nano-microstructure, so that a liquid metal film may be formed.

According to an embodiment, the metal nanoparticle-coated substrate may form a metal surface with a nano-microstructure. The nano-microstructure may have a size of about 500 nm to about 500 μm. The coating of the metal nanoparticle-coated substrate with the liquid metal may include coating the metal nanoparticle-coated substrate with the liquid metal while the liquid metal spontaneously and selectively flows along the nano-microstructure. The liquid metal applied onto the metal nanoparticle-coated substrate may have a thickness of about 500 nm to about 500 μm.

If the size of the nano-microstructure is out of the above range, a complete wetting may fail to occur because the imbibition phenomenon of the liquid metal does not occur, and accordingly, it is impossible to form a liquid metal film.

In general, an additional external force for coating is required to form a liquid metal film. However, in the coating with the liquid metal in the present disclosure, the liquid metal may flow along a nano-microstructure pattern and may be thinly and spontaneously applied.

When a liquid metal droplet is dropped and an acid vapor treatment is performed, a uniform liquid metal film may be formed through a complete wetting phenomenon as the liquid metal spontaneously spreads along the nano-microstructure region through the imbibition phenomenon. The complete wetting phenomenon may appear within one minute after the acid vapor treatment, and coating may be completed quickly and uniformly without an additional external force. This is a new spontaneous coating method, which is different from general coating by an external force such as pressure or rolling, and selective coating of the liquid metal without an additional process may be performed by patterning the microstructure region into a desired shape.

The applied liquid metal itself may be a liquid metal film. The thickness of the liquid metal film may be adjusted by adjusting the size of the nano-microstructure, a uniform liquid metal film may be provided, and the liquid metal may be spontaneously and thinly applied over a large area without a complicated process.

The method may further include, prior to the preparing of the metal nanoparticle-coated substrate by spray coating the metal nanoparticles, forming a masking. The forming of the masking may be performed with a photo mask or a metal mask, and the masking may be forming a pattern during the spray coating.

The method may further include forming a masking for patterning of a nano-microstructure. The masking may be formed on a polymer or silicon substrate or formed on a polymer or silicon substrate on which a metal layer is formed. Through the masking, spray coating with metal nanoparticles may be performed in a desired pattern, and accordingly, the nano-microstructure may be patterned. The liquid metal may be spontaneously applied along the patterned nano-microstructure, and thus, selective coating with a liquid metal may be possible.

The present disclosure may provide a new coating and pattern formation technology using an imbibition phenomenon of a liquid metal on a surface of a substrate, on which a nano-microstructure is easily formed, using spray coating of metal nanoparticles. The above method of manufacturing the liquid metal film may provide a stable, spontaneous and rapid coating technology using a liquid metal, which is uncontrollable due to its high surface tension, and may enable coating to be performed over a wide range within a relatively short time because there is no need for expensive equipment or external force. In addition, by controlling a nano-microstructure region, selection and patterning of the liquid metal may be possible. The above spontaneous and easy method of manufacturing the liquid metal film may be a core technology to allow a liquid metal to be more actively used as an electrode material of a portable wearable device.

Hereinafter, the present disclosure will be described in more detail with reference to examples and comparative examples.

However, the following examples are only for illustrating the present disclosure, and the present disclosure is not limited to the following examples.

### Preparation Example

A microstructure was formed on polydimethylsiloxane (PDMS) as a polymer substrate through a photolithography process and copper was deposited, to prepare a microstructured metal substrate.

### Example 1

A cylindrical microstructure was formed through a photolithography process. The cylindrical microstructure was prepared with a height of 25 μm, a width of 25 μm, and a pitch of 50 μm.

### Example 2

A pyramid-shaped microstructure was formed through a photolithography process. The pyramid-shaped microstructure was prepared with a height of 18 μm, a width of 25 μm, and a pitch of 25 μm.

### Example 3

A cylindrical microstructure was formed through a photolithography process. The cylindrical microstructure was prepared with a height of 25 μm, a width of 50 μm, and a pitch of 100 μm.

### Example 4

A cylindrical microstructure was formed through a photolithography process. The cylindrical microstructure was prepared with a height of 25 μm, a width of 100 μm, and a pitch of 200 μm.

### Comparative Example 1

Copper was deposited on a polymer substrate instead of forming a microstructure, to prepare a metal substrate.

### Comparative Example 2

A cylindrical microstructure was formed through a photolithography process. The cylindrical microstructure was prepared with a height of 25 μm, a width of 200 μm, and a pitch of 400 μm.

### Experimental Example 1: Comparison of Contact Angle of Liquid Metal According to Formation of Microstructure

An EGaIn as a liquid metal was treated with hydrochloric acid (HCl) vapor on a metal substrate formed with microstructures of the examples and comparative examples, the metal substrate was coated with a liquid metal, and a contact angle was measured using a drop-shape analyzer (DSA100S, KRUSS, Germany) over time.

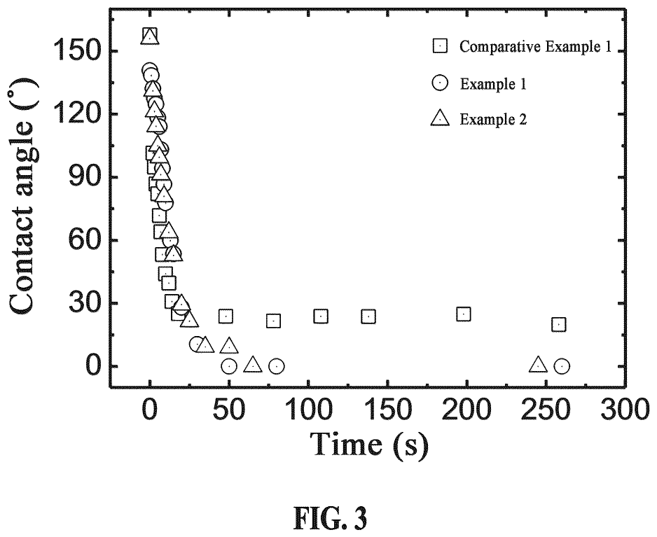

FIG. 3 illustrates a contact angle of a liquid metal according to examples and comparative examples of the present disclosure. Referring to FIG. 3, it can be confirmed that in the case of a metal substrate including the microstructures of Examples 1 and 2, the contact angle decreases to 0° within 1 minute. This indicates that a complete wetting phenomenon of the liquid metal was induced. In contrast, it can be confirmed that in Comparative Example 1, the contact angle does not decrease to 250 or less over time. Therefore, it can be found that the metal substrate including the microstructures may exhibit the effect of spontaneous complete wetting through the imbibition phenomenon of the liquid metal in comparison to a substrate on which a microstructure is not formed, and that the contact angle converges to 0° within an extremely short period of time.

### Experimental Example 2: Comparison of Contact Angle of Liquid Metal According to Size of Microstructure

An EGaIn as a liquid metal was treated with HCl vapor on a metal substrate formed with microstructures of the examples and comparative examples, the metal substrate was coated with a liquid metal, and a contact angle was measured using a drop-shape analyzer (DSA100S, KRUSS, Germany) over time.

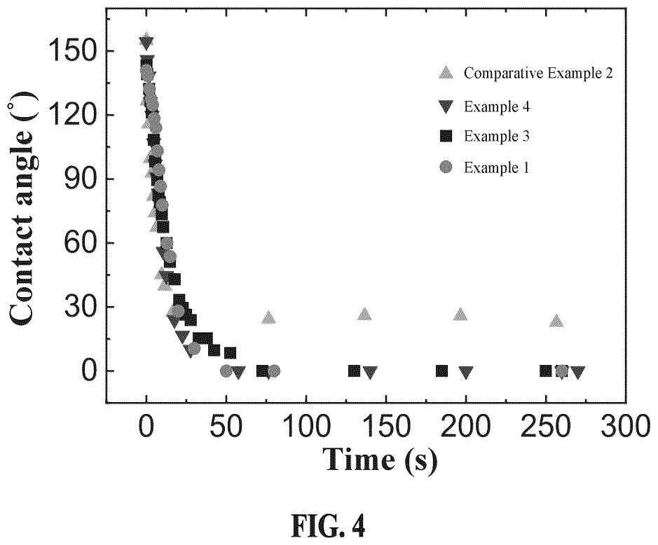

FIG. 4 illustrates a contact angle of a liquid metal according to examples and comparative examples of the present disclosure. Referring to FIG. 4, it can be confirmed that when the width and the pitch of the microstructure of Comparative Example 2 are 200 μm and 400 μm, respectively, the contact angle is greater than 25°, which indicates an incomplete wetting phenomenon. In addition, it was mathematically confirmed that an imbibition phenomenon does not occur in Comparative Example 2, based on a Wenzel's model. Comparing Examples 1, 3, and 4, it was confirmed that the complete wetting effect fast occurs, as the size of the microstructure decreases. In addition, it was found that when the size of the microstructure is greater than or equal to a predetermined numerical value, an imbibition phenomenon does not occur, which makes it impossible to induce a spontaneous complete wetting phenomenon, and thus, it is impossible to manufacture a spontaneous, selective, uniform liquid metal film.

### Example 5

PMMA as a polymer substrate was coated with a spray solution, in which 2 wt % of copper nanoparticles with the size of 500 nm were dispersed in dichloromethane as a solvent, at a velocity of 0.1 mL/s and a distance of 10 cm for 2 minutes, to prepare a metal nanoparticle-coated substrate. Spontaneous coating was induced through an HCl vapor treatment of an EGaIn as a liquid metal on the metal nanoparticle-coated substrate.

### Example 6

A metal layer was formed by depositing copper on a silicon substrate through a vacuum deposition process. The metal layer was coated with a solution, in which 2 wt % of copper nanoparticles with the size of 500 nm were dispersed in IPA as a solvent, at a velocity of 0.1 mL/s and a distance of 15 cm for 3 minutes, to prepare a metal nanoparticle-coated substrate. Spontaneous coating was induced through an HCl vapor treatment of an EGaIn as a liquid metal on the metal nanoparticle-coated substrate.

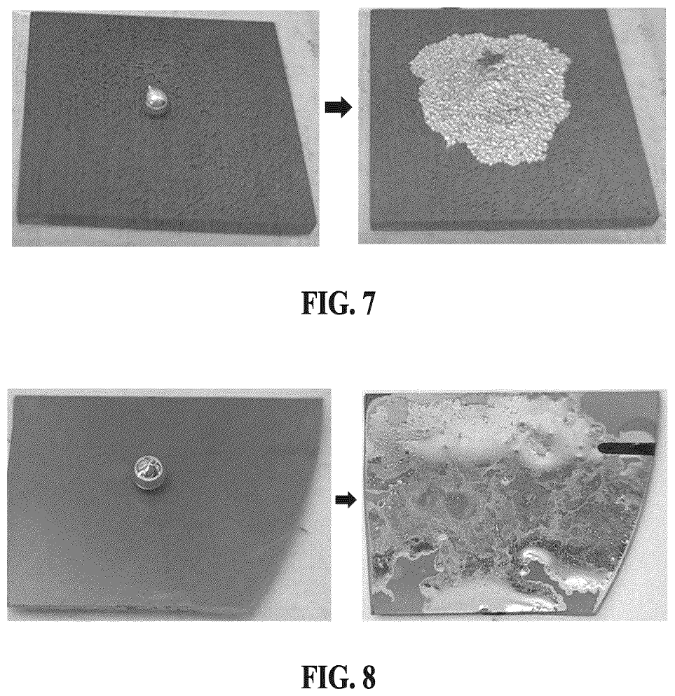

FIGS. 7 and 8 illustrate examples of liquid metals applied according to an embodiment. FIG. 7 illustrates a liquid metal applied according to Example 5, and FIG. 8 illustrates a liquid metal applied according to Example 6. Referring to FIGS. 7 and 8, since an imbibition phenomenon of a liquid metal remarkably appears along a nano-microstructure formed on a metal nanoparticle-coated substrate, it can be confirmed that a substrate is spontaneously coated with the liquid metal after an acid vapor treatment was performed on liquid metal droplets.

Thus, it can be found that the method of manufacturing the liquid metal film according to an embodiment induces a spontaneously applying of the liquid metal onto a metallic surface having a nano-microstructure without a need for an external force by spray coating metal nanoparticles. A vacuum deposition process or a lithography process is generally required to obtain a metallic surface having a nano-microstructure, whereas, in the present disclosure, a metallic surface having a nano-microstructure may be easily prepared through a spray process of metal nanoparticles.

While the embodiments have been described above, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A method of manufacturing a liquid metal film, the method comprising:
forming a microstructure on a polymer substrate;
preparing a microstructured metal substrate by depositing a metal on the polymer substrate on which the microstructure is formed; and
coating the microstructured metal substrate with a liquid metal.

2. The method of claim 1, wherein
the polymer substrate comprises at least one selected from a group consisting of polydimethylsiloxane (PDMS), polyurethane acrylate (PUA), poly(vinyl alcohol) (PVA), polyvinyl chloride (PVC), polytetrafluoroethylene (PTFE), styrene ethylene butylene styrene (SEBS), polyolefin, polystyrene, polyester, polyacrylate, polyimide, and Ecoflex,
the metal comprises at least one selected from a group consisting of copper, gold, chromium, silver, platinum, zinc, nickel, tin, and iron, and
the liquid metal comprises gallium; or a gallium-based alloy comprising gallium and at least one metal selected from a group consisting of indium, tin, and zinc.

3. The method of claim 1, wherein
the forming of the microstructure is performed by a photolithography process, a soft lithography process, a nanoimprinting process, a three-dimensional (3D) printer process, a particle coating method, or a surface grinding method,
the microstructure comprises at least one structure selected from a group consisting of a cylinder, a pyramid, a hemisphere, and a polygonal pillar, and
the microstructure has a height of about 1 micrometer (μm) to about 200 μm, a width of about 1 μm to about 200 μm, and a pitch of about 1 μm to about 100 μm.

4. The method of claim 1, wherein
the preparing of the microstructured metal substrate by depositing the metal is performed by a vacuum deposition process,
the coating of the microstructured metal substrate with the liquid metal is performed by an acid vapor treatment of the liquid metal on the microstructured metal substrate, and
the acid vapor treatment is a treatment of vapor of at least one acid solution selected from a group consisting of a hydrochloric acid, a nitric acid, a sulfuric acid, a bromic acid, and a perchloric acid.

5. The method of claim 1, wherein
the coating of the microstructured metal substrate with the liquid metal comprises coating the microstructured metal substrate with the liquid metal while the liquid metal spontaneously and selectively flows along the microstructure, and
the liquid metal applied onto the microstructured metal substrate has a thickness of about 1 μm to about 200 μm.

6. A method of manufacturing a liquid metal film, the method comprising:
preparing a metal nanoparticle-coated substrate by spray coating a polymer or silicon substrate with metal nanoparticles; and
coating the metal nanoparticle-coated substrate with a liquid metal.

7. The method of claim 6, further comprising, prior to the preparing of the metal nanoparticle-coated substrate:
forming a metal layer by depositing a metal on the polymer or silicon substrate.

8. The method of claim 7, wherein
the polymer substrate comprises at least one selected from a group consisting of polydimethylsiloxane (PDMS), polymethyl methacrylate (PMMA), polyurethane acrylate (PUA), polytetrafluoroethylene (PTFE), styrene ethylene butylene styrene (SEBS), polypropylene, polystyrene, polyester, polyimide, and Ecoflex,
the metal comprises at least one selected from a group consisting of copper, gold, silver, platinum, zinc, nickel, tin, and iron,
the metal nanoparticles comprise at least one selected from a group consisting of copper, gold, silver, platinum, zinc, nickel, tin, and iron, and
the liquid metal comprises gallium; or a gallium-based alloy comprising gallium and at least one metal selected from a group consisting of indium, tin, and zinc.

9. The method of claim 6, wherein
a solution used for the spray coating comprises at least one solvent selected from a group consisting of dichloromethane, acetone, methyl alcohol, ethyl alcohol, isopropyl alcohol, tetrahydrofuran, dimethylformamide, hexane, cyclohexanone, toluene, chloroform, dichlorobenzene, acrylonitrile, and dimethyl sulfoxide,
the metal nanoparticles are in an amount of about 0.1% by weight (wt %) to about 80 wt % in the solution,
the metal nanoparticles have a size of about 100 nanometers (nm) to about 500 micrometers (μm), and
the spray coating is performed at a distance of about 5 centimeters (cm) to about 50 cm and a velocity of about 1 microliter per second (μL/s) to about 10 milliliters per second (mL/s) for a period of about 1 second to about 20 minutes.

10. The method of claim 6, wherein
the metal nanoparticle-coated substrate forms a metal surface with a nano-microstructure,
the nano-microstructure has a size of about 500 nm to about 500 μm,
the coating of the metal nanoparticle-coated substrate with the liquid metal comprises coating the metal nanoparticle-coated substrate with the liquid metal while the liquid metal spontaneously and selectively flows along the nano-microstructure, and
the liquid metal applied onto the metal nanoparticle-coated substrate has a thickness of about 500 nm to about 500 μm.
